(19) United States
(12) Patent Application Publication
(10) Pub. No.: US 2026/0064624 A1
(43) Pub. Date: Mar. 5, 2026

(54) WORD ALIGNMENT FOR CHIP-TO-CHIP COMMUNICATION

(71) Applicant: QUALCOMM Incorporated, San Diego, CA (US)

(72) Inventors: Masoud ROHAM, San Diego, CA (US); Chad Everett WINEMILLER, Cary, NC (US); Seuk SON, San Diego, CA (US); Thimmaiah BOLKARANDA SUBBAIAH, San Diego, CA (US)

(21) Appl. No.: 18/818,037

(22) Filed: Aug. 28, 2024

(51) Int. Cl. G06F 13/42

(52) U.S. Cl. CPC G06F 13/4291

(57) ABSTRACT

A system includes a deserializer having a data input, a clock input, and parallel outputs, wherein the deserializer is configured to receive a serial data stream at the data input, convert the serial data stream into parallel data, and output the parallel data at the parallel outputs. The system also includes an edge swallower or a pulse swallower coupled to the clock input of the deserializer.

### BACKGROUND

### Field

Aspects of the present disclosure relate generally to chip-to-chip communication, and, more particularly, to word alignment for chip-to-chip communication.

### Background

A system may include a first chip and a second chip in which the first chip and the second chip communicate with each other using serializer/deserializer (SerDes). For example, to support communication from the first chip to the second chip, the SerDes may include a serializer and a driver on the first chip and a receiver and a deserializer on the second chip. On the first chip, the serializer converts parallel data into a serial data stream and the driver transmits the serial data stream to the second chip via a high-speed serial link (i.e., channel) between the first chip and the second chip. On the second chip, the receiver receives the serial data stream, and the deserializer converts the received serial data stream back into parallel data.

### SUMMARY

The following presents a simplified summary of one or more implementations in order to provide a basic understanding of such implementations. This summary is not an extensive overview of all contemplated implementations and is intended to neither identify key or critical elements of all implementations nor delineate the scope of any or all implementations. Its sole purpose is to present some concepts of one or more implementations in a simplified form as a prelude to the more detailed description that is presented later.

A first aspect relates to a system. The system includes a deserializer having a data input, a clock input, and parallel outputs, wherein the deserializer is configured to receive a serial data stream at the data input, convert the serial data stream into parallel data, and output the parallel data at the parallel outputs. The system also includes an edge swallower coupled to the clock input of the deserializer.

A second aspect relates to a system. The system includes a deserializer having a data input, a clock input, and parallel outputs, wherein the deserializer is configured to receive a serial data stream at the data input, convert the serial data stream into parallel data, and output the parallel data at the parallel outputs. The system includes a pulse swallower coupled to the clock input of the deserializer.

A third aspect relates to a method of word alignment. The method includes comparing a word at parallel outputs of a deserializer with a pattern, determining the word does not match the pattern, in response to determining the word does not match the pattern, swallowing an edge of a clock signal, and inputting the clock signal to a clock input of the deserializer after the edge is swallowed.

A fourth aspect relates to a method of word alignment. The method includes comparing a word at parallel outputs of a deserializer with a pattern, determining the word does not match the pattern, in response to determining the word does not match the pattern, swallowing a pulse of a clock signal, and inputting the clock signal to a clock input of the deserializer after the pulse is swallowed.

### BRIEF DESCRIPTION OF THE DRAWINGS

FIG. 1 shows an example of a system including a first chip and a second chip in which the first chip includes a serializer and the second chip includes a deserializer according to certain aspects of the present disclosure.

FIG. 2A illustrates an example of word misalignment between the first chip and the second chip according to certain aspects of the present disclosure.

FIG. 2B illustrates an example in which data words from the first chip are reassembled at the second chip according certain aspects of the present disclosure.

FIG. 3 shows an example in which the second chip includes an edge swallower for shifting a word boundary of the deserializer according to certain aspects of the present disclosure.

FIG. 4 shows an exemplary implementation of the edge swallower including a complementary clock generator and a multiplexer according to certain aspects of the present disclosure.

FIG. 5 is a timing diagram showing an example of edge swallowing according certain aspects of the present disclosure.

FIG. 6 shows an exemplary implementation of the complementary clock generator and the multiplexer according certain aspects of the present disclosure.

FIG. 7 is a timing diagram showing another example of edge swallowing according to certain aspects of the present disclosure.

FIG. 8 is a flowchart illustrating an example of a word alignment method according to certain aspects of the present disclosure.

FIG. 9 shows an example in which the system uses a full-rate clock signal for chip-to-chip communication according to certain aspects of the present disclosure.

FIG. 10 shows an example in which the second chip includes a pulse swallower for shifting the word boundary of the deserializer according to certain aspects of the present disclosure.

FIG. 11 shows an exemplary implementation of the pulse swallower including a clock gating circuit and a gating control circuit according to certain aspects of the present disclosure.

FIG. 12 shows an exemplary implementation of the gating control circuit according to certain aspects of the present disclosure.

FIG. 13 is a flowchart illustrating another example of a word alignment method according to certain aspects of the present disclosure.

FIG. 14 is a flowchart illustrating yet another example of a word alignment method according to certain aspects of the present disclosure.

FIG. 15 is a flowchart illustrating still another example of a word alignment method according to certain aspects of the present disclosure.

### DETAILED DESCRIPTION

The detailed description set forth below, in connection with the appended drawings, is intended as a description of various configurations and is not intended to represent the only configurations in which the concepts described herein may be practiced. The detailed description includes specific details for the purpose of providing a thorough understanding of the various concepts. However, it will be apparent to those skilled in the art that these concepts may be practiced without these specific details. In some instances, well-known structures and components are shown in block diagram form in order to avoid obscuring such concepts.

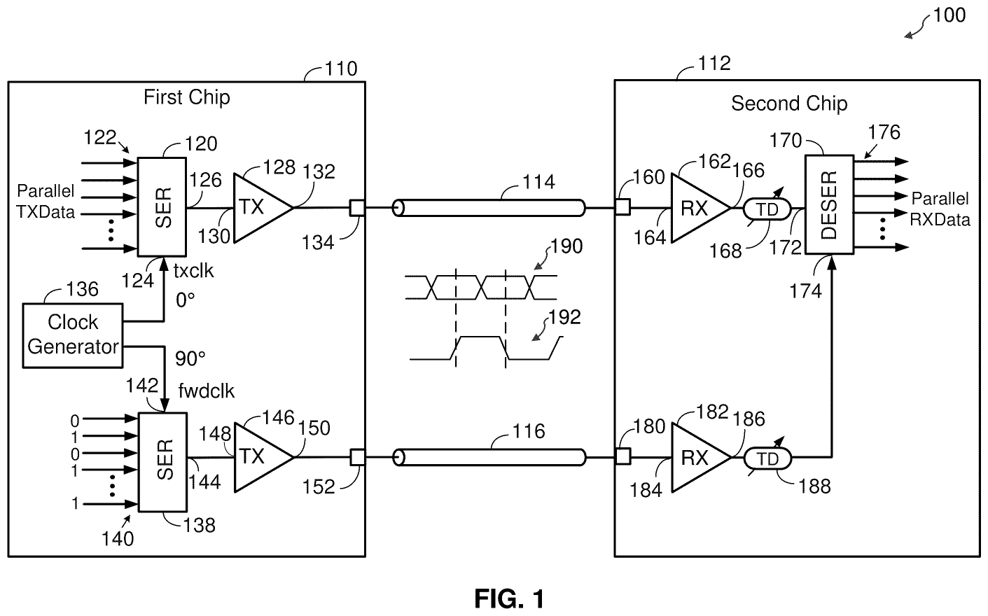

FIG. 1 shows an example of a system 100 including a first chip 110 and a second chip 112, in which the first chip 110 and the second chip 112 communicate with each other using SerDes. In certain aspects, the first chip 110 and the second chip 112 may be packaged together to put the entire system 100 in a single package. In this example, each of the chips 110 and 112 includes circuits for performing a respective subset of the functions of the system 100. Using multiple chips (e.g., the first and second chips 110 and 112) to implement the system 100 may help improve yield and make better use of advanced and high-cost technology nodes compared with trying to integrate the entire system 100 on a single chip. In this example, each of the chips 110 and 112 may also be referred to as a chiplet or another term. It is to be appreciated that the system 100 is not limited to this example, and that the first chip 110 and the second chip 112 need not be packaged together in other implementations.

In the example shown in FIG. 1, the first chip 110 includes a serializer 120, a first driver 128, a clock generator 136, a replica serializer 138, and a second driver 146. The second chip 112 includes a first receiver 162, a first tunable delay circuit 168, a deserializer 170, a second receiver 182, and a second tunable delay circuit 188. It is to be appreciated that each of the chips 110 and 112 includes additional circuits (e.g., one or more processors) not shown in FIG. 1.

In this example, the system 100 includes a first link 114 (i.e., first channel) coupled between the first chip 110 and the second chip 112, and a second link 116 (i.e., second channel) coupled between the first chip 110 and the second chip 112. As discussed further below, the first link 114 is a serial link used for transporting the serial data stream from the first chip 110 to the second chip 112. The serial link may be a differential serial link or a single-ended serial link. The second link 116 is used for transporting a clock signal from the first chip 110 and the second chip 112. As discussed further below, the clock signal is used for timing operations of the deserializer 170 on the second chip 112. In certain aspects, the first chip 110 and the second chip 112 may be mounted on a package substrate in which each of the first and second links 114 and 116 may include one or more metal traces on and/or embedded in the package substrate. However, it is to be appreciated that the present disclosure is not limited to this example.

In the example in FIG. 1, the serializer 120 has multiple parallel inputs 122 configured to receive data in parallel, a clock input 124 coupled to the clock generator 136, and an output 126. The first driver 128 has an input 130 coupled to the output 126 of the serializer 120, and an output 132 coupled to the first link 114 via a first pad 134 (also referred to as a pin). The replica serializer 138 has multiple parallel inputs 140 configured to receive alternating ones and zeros, a clock input 142 coupled to the clock generator 136, and an output 144. The second driver 146 has an input 148 coupled to the output 144 of the replica serializer 138, and an output 150 coupled to the second link 116 via a second pad 152.

The first receiver 162 has an input 164 coupled to the first link 114 via a first pad 160, and an output 166. The deserializer 170 has a data input 172, a clock input 174, and multiple parallel outputs 176. The first tunable delay circuit 168 is coupled between the output 166 of the first receiver 162 and the data input 172 of the deserializer 170. The second receiver 182 has an input 184 coupled to the second link 116 via a second pad 180, and an output 186. The second tunable delay circuit 188 is coupled between the output 186 of the second receiver 182 and the clock input 174 of the deserializer 170.

In operation, the clock generator 136 is configured to generate a transmit clock signal (labeled “txclk”) and a forward clock signal (labeled “fwdclk”). The transmit clock signal and the forward clock signal have the same frequency, in which the forward clock signal is 90 degrees out of phase with the transmit clock signal. As discussed further below, the frequency of the transmit clock signal and the forward clock signal is half the frequency or data rate of the serial data stream (i.e., the transmit clock signal and the forward clock signal are half-rate clock signals). The clock generator 136 may be implemented with a phase-locked loop (PLL), a delay-locked loop (DLL), or any combination thereof.

The serializer 120 is configured to receive parallel data at the parallel inputs 122 (e.g., from a processor on the first chip 110), convert the parallel data into a serial data stream, and output the serial data stream at the output 126. The serializer 120 is also configured to receive the transmit clock signal (labeled “txclk”) and time the parallel-to-serial conversion operations based on the transmit clock signal. In certain aspects, the serializer 120 is configured to output one bit of the serial data stream for each edge of the transmit clock signal. Since the transmit clock signal has two edges (i.e., a rising edge and a falling edge) per clock period, this causes the serializer 120 to output two bits of the serial data stream per clock period. As a result, the data rate of the serial data stream is twice the frequency of the transmit clock signal. The first driver 128 is configured to receive the serial data stream at the input 130 and transmit the serial data stream to the second chip 112 via the first link 114 (i.e., serial link).

The replica serializer 138 is configured to receive the forward clock signal (labeled “fwdclk”) at the clock input 142, and regenerate the forward clock signal at the output 144 by sequentially outputting the alternating ones and zeros at the inputs 140 on both rising and falling edges of the forward clock signal. The replica serializer 138 may have the same or similar structure as the serializer 120. This allows the replica serializer 138 to mimic the time delays in the serializer 120 so that the timing of the forward clock signal at the output 144 accounts for the time delays in the serializer 120. The second driver 146 is configured to receive the forward clock signal at the input 148 and transmit the clock signal to the second chip 112 via the second link 116.

It is to be appreciated that the first chip 110 is not limited to the example shown in FIG. 1. For example, in some implementations, the replica serializer 138 may be omitted in which the forward clock signal from the clock generator 136 is routed to the input 148 of the second driver 146 without the replica serializer 138.

At the second chip 112, the first receiver 162 is configured to receive the serial data stream at the input 164 via the first link 114, and output the received serial data stream at the output 166. In some implementations, the first receiver 162 may include an equalizer to compensate for frequency-dependent signal attenuation in the first link 114. The first tunable delay circuit 168 delays the received serial data stream by a tunable delay to adjust the timing of the received serial data stream.

The second receiver 182 is configured to receive the forward clock signal at the input 184 via the second link 116, and output the received forward clock signal at the output 186. The second tunable delay circuit 188 delays the received forward clock signal by a tunable delay to adjust the timing of the received forward clock signal. In certain aspects, the first tunable delay circuit 168 and/or the second tunable delay circuit 188 may be used to adjust the timing of the received forward clock signal from the output 186 of the second receiver 182 with respect to the received serial data stream from the output 166 of the first receiver 162. This may be done, for example, to compensate for skew between the serial data stream and the forward clock signal due to mismatches between the path of the serial data stream and the path of the forward clock signal).

The deserializer 170 is configured to sequentially capture data bits in the received serial data stream on both rising and falling edges of the received forward clock signal, and output the captured data bits in parallel at the parallel outputs 176. For example, the parallel outputs 176 may include N outputs where N is an integer. In this example, the deserializer 170 may be configured to output every N consecutive bits in the received serial data stream in parallel where each of the N consecutive bits is output at a respective one of the N outputs.

To reliably capture data bits in the received serial data stream at the deserializer 170, the edges of the forward clock signal at the clock input 174 may be centered between data transitions in the received serial data stream. In this regard, FIG. 1 shows an example of the received serial data stream 190 and an example of the forward clock signal 192 at the clock input 174 in which the edges of the forward clock signal 192 are centered between the data transitions in the received serial data stream 190. In this example, the 90-degree phase shift between the transmit clock signal (labeled “txclk”) and the forward clock signal (labeled “fwdclk”) helps center the edges of the forward clock signal 192 between the data transitions in the received serial data stream 190.

It is to be appreciated that the system 100 is not limited to the example shown in FIG. 1. For example, it is to be appreciated that the system 100 may include one or more additional elements in the path of the serial data path and/or one or more additional elements in the path of the forward clock signal. It is also to be appreciated that the system 100 may include multiple serial links between the first chip 110 and the second chip 112 in which the exemplary SerDes circuits shown in FIG. 1 may be duplicated for each of the serial links.

In certain aspects, the serializer 120 receives parallel data at the inputs 122 in data words. Each data word includes N bits (e.g., 16 bits) that are received in parallel at the inputs 122, in which each of the N bits of the data word is received at a respective one of the inputs 122. In these aspects, the serializer 120 sequentially outputs the N bits of a data word in the serial data stream based on the transmit clock signal (labeled “txclk”). More particularly, the serializer 120 outputs one bit of the data word in the serial data stream for each one of N edges of the transmit clock signal.

At the second chip 112, the deserializer 170 outputs parallel data at the outputs 176 in data words where each data word includes N bits of the received serial data stream. The deserializer 170 outputs each bit of a data word at a respective one of the outputs 176. In this example, the deserializer 170 captures the bits for a data word from the serial data stream based on the received forward clock signal. More particularly, the deserializer 170 captures each bit of the data word on a respective edge of the forward clock signal.

A challenge with receiving data words at the serializer 120 and outputting data words at the deserializer 170 is that the data words at the deserializer 170 may not be aligned with the data words at the serializer 120. As a result, each data word output by the deserializer 170 includes portions of two data words at the serializer 120.

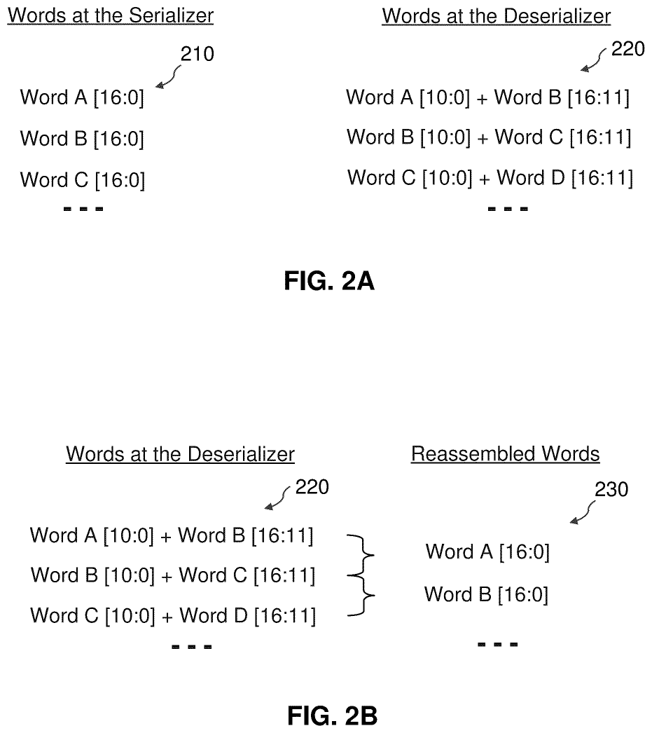

In this regard, FIG. 2A shows an example of word misalignment between the serializer 120 and the deserializer 170. In the example in FIG. 2A, the serializer 120 receives data words 210 at the parallel inputs 122 in which the data words are denoted Word A, Word B, Word C, and so forth. The deserializer 170 outputs data words 220 at the parallel outputs 176 where the contents of each data word output by the deserializer 170 is shown in a respective row in FIG. 2A. As shown in FIG. 2A, each of the data words output by the deserializer 170 includes portions of two of the data words at the serializer 120. For example, the first word output by the deserializer 170 shown in FIG. 2A includes a portion of Word A and a portion of Word B.

One approach to address word misalignment is to reassemble (i.e., reconstruct) the data words from the first chip 110 at the second chip 112. In this approach, the second chip 112 includes a buffer configured to temporarily store at least two words output by the deserializer 170 at a time. During initial setup, the first chip 110 transmits a known pattern to the second chip 112 via the first link 114. A processor at the second chip 112 searches for the known pattern in the buffer in order to identify a word boundary. After the processor identifies the word boundary, the processor reassembles (i.e., reconstructs) the data words from the first chip 110 using the data words stored in the buffer.

In this regard, FIG. 2B shows an example in which the processor at the second chip 112 reassembles data words 230 from the first chip 110 using the data words stored in the buffer. In this example, the processor uses the identified word boundary to identify the portions of the Word A that are contained in two of the words stored in the buffer and combines the portions of the Word A to reassemble the Word A. Similarly, the processor uses the identified word boundary to identify the portions of the Word B that are contained in two of the words stored in the buffer and combines the portions of the Word B to reassemble the Word B.

Reassembling the data words using the above approach requires storing at least two data words at a time in the buffer, which increases latency.

Another approach for addressing word misalignment is to include an indicator indicating the beginning of a word in a separate parallel lane. However, this approach increases power and reduces link efficiency. Yet another approach is to encode the data to signify word boundaries. However, this approach increases power for performing calculations and reduces link efficiency.

To address the above, aspects of the present disclosure provide an edge swallower in the clock path of the deserializer 170, in which the edge swallower is configured to shift the word boundary at the deserializer 170 by swallowing edges of the clock signal (e.g., the clock signal from the first chip 110) in the clock path. For example, a controller on the second chip 112 may cause the edge swallower to sequentially shift the word boundary at the deserializer 170 until word alignment is achieved between the serializer 120 and the deserializer 170. Shifting the word boundary at the deserializer 170 using the edge swallower in the clock path to achieve word alignment has the advantage of not adding latency in the data path. The above features and other features of the present disclosure are discussed further below.

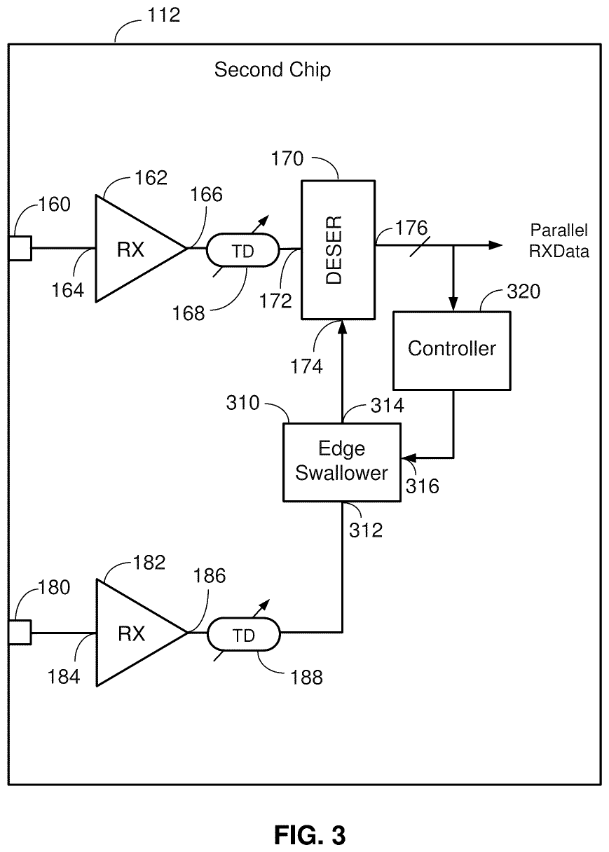

FIG. 3 shows an example in which the second chip 112 also includes an edge swallower 310 and a controller 320. The edge swallower 310 is in the clock path of the deserializer 170. In the example shown in FIG. 3, the edge swallower 310 is positioned between the second tunable delay circuit 188 and the clock input 174 of the deserializer 170. However, it is to be appreciated that the present disclosure is not limited to this example, and that the edge swallower 310 may be positioned at other locations in the clock path of the deserializer 170 in other implementations.

In this example, the edge swallower 310 has a clock input 312, a control input 316, and an output 314. The clock input 312 of the edge swallower 310 is coupled to the second receiver 182 through the second tunable delay circuit 188 (which may be omitted in some implementations). In this example, the clock input 312 receives the clock signal received by the second receiver 182 from the first chip 110 (shown in FIG. 1). However, it is to be appreciated that the present disclosure is not limited to this example, and that the clock signal may come from another source (e.g., a clock data recovery circuit located on the second chip 112) in other implementations. The output 314 of the edge swallower 310 is coupled to the clock input 174 of the deserializer 170, and the control input 316 of the edge swallower 310 is coupled to the controller 320.

The controller 320 is coupled to the outputs 176 of the deserializer 170 and the edge swallower 310. In FIG. 3, the outputs 176 of the deserializer 170 are represented by an arrow with a slash indicating multiple parallel outputs. The controller 320 may be implemented with a general-purpose processor, a digital signal processor (DSP), a central processing unit (CPU), a microcontroller, an application specific integrated circuit (ASIC), a field programmable gate array (FPGA), a programmable logic device, or any combination thereof.

The edge swallower 310 is configured to shift the word boundary at the deserializer 170 by swallowing edges of the clock signal received at the input 312 and outputting the clock signal after the edge swallowing to the clock input 174 of the deserializer 170. For example, the edge swallower 310 may shift the word boundary at the deserializer 170 by one bit position for each edge of the clock signal that is swallowed. The edge may be a rising edge or a falling edge of the clock signal. In certain aspects, the edge swallower 310 is configured to swallow edges of the clock signal based on a control signal received at the control input 316 from the controller 320, as discussed further below.

In certain aspects, the controller 320 is configured to cause the edge swallower 310 to sequentially shift the word boundary at the deserializer 170 until word alignment is achieved between the serializer 120 and the deserializer 170. For example, during an initial setup, the first chip 110 may transmit a known pattern (e.g., pattern of bits) to the second chip 112 one or more times via the first link 114. In this example, word alignment occurs when a data word output by the deserializer 170 matches the pattern. In this example, the controller 320 may cause the edge swallower 310 to sequentially shift the word boundary at the deserializer 170 (e.g., sequentially swallow clock edges) until a data word output by the deserializer 170 matches the pattern indicating word alignment. As a result, word alignment is achieved without the need for data encoding or an extra lane to indicate word boundaries, both of which increase power and reduce link efficiency. In addition, word alignment is achieved without adding latency to the data path.

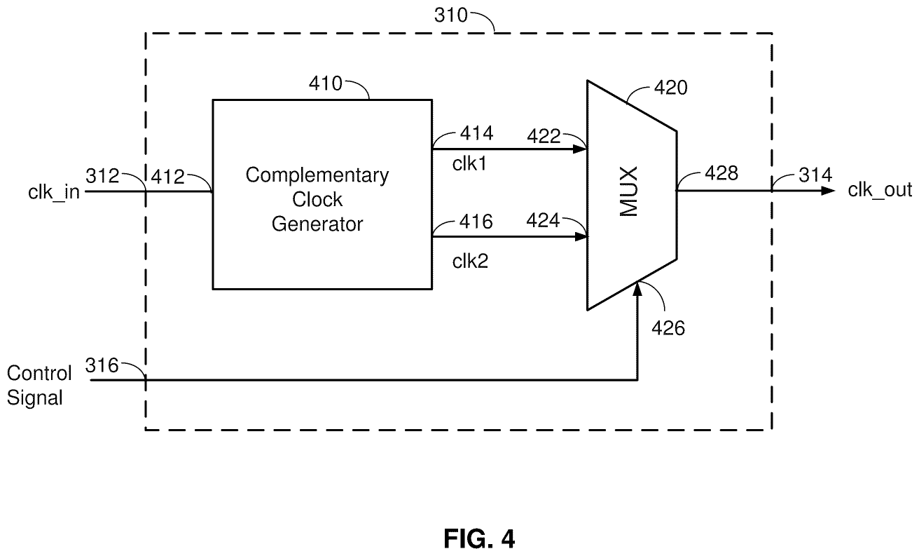

FIG. 4 shows an exemplary implementation of the edge swallower 310 according to certain aspects. In this example, the edge swallower 310 includes a complementary clock generator 410 and a multiplexer 420 according to certain aspects. The complementary clock generator 410 has an input 412 coupled to the clock input 312, a first output 414, and a second output 416. The multiplexer 420 has a first input 422 coupled to the first output 414 of the complementary clock generator 410, a second input 424 coupled to the second output 416 of the complementary clock generator 410, a select input 426 coupled to the control input 316, and an output 428 coupled to the output 314.

In this example, the complementary clock generator 410 is configured to receive the clock signal at the clock input 312 (labeled “clk_in”), and generate a first clock signal (labeled “clk1”) and a second clock signal (labeled “clk2”) based on the received clock signal, in which the first clock signal and the second clock signal are complementary clock signals. The first and second clock signals may have the same frequency as the clock signal at the clock input 312.

The multiplexer 420 is configured to receive the first clock signal (labeled “clk1”) at the first input 422, receive the second clock signal (labeled “clk2”) at the second input 424, and receive a control signal from the controller 320 at the select input 426. The multiplexer 420 is also configured to select one of the first and second clock signals based on the control signal from the controller 320, and output the selected one of the first and second clock signals at the output 314. For example, the multiplexer 420 may be configured to select the first clock signal when the control signal is high (i.e., logic one) and select the second clock signal when the control signal is low (i.e., logic zero), or vice versa.

In this example, the controller 320 causes the edge swallower 310 to swallow a clock edge by causing the multiplexer 420 to switch from the first clock signal to the second clock signal or switch from the second clock signal to the first clock signal using the control signal. For example, when the first clock signal is currently selected by the multiplexer 420, the controller 320 may cause the multiplexer 420 to swallow a clock edge by causing the multiplexer 420 to switch from the first clock signal to the second clock signal (e.g., toggling the control signal from high to low). When the second clock signal is currently selected by the multiplexer 420, the controller 320 may cause the multiplexer 420 to swallow a clock edge by causing the multiplexer 420 to switch from the second clock signal to the first clock signal (e.g., toggling the control signal low to high). Thus, in this example, the controller 320 causes the edge swallower 310 to swallow a clock edge by toggling the control signal from high to low (i.e., one to zero) or toggling the clock signal low to high (i.e., zero to one).

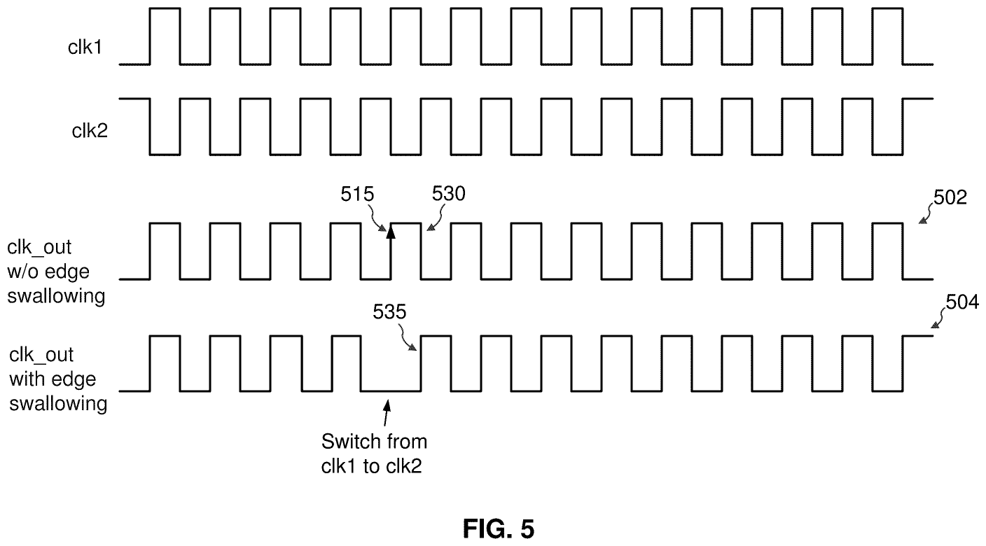

An example of clock edge swallowing by switching from the first clock signal to the second clock signal is illustrated in FIG. 5. FIG. 5 is a timing diagram showing an example of the first clock signal (labeled “clk1”), an example of the second clock signal (labeled “clk2”), an example of the output clock signal 502 without edge swallowing, and an example of the output clock signal 504 with edge swallowing. The output clock signal is the clock signal at the output 314 of the edge swallower 310 is this example.

In the example shown in FIG. 5, the multiplexer 420 selects the first clock signal for the output clock signal 502 without edge swallowing. In this example, the output clock signal 502 without edge swallowing includes clock edge 515.

For the output clock signal 504 with edge swallowing, the multiplexer 420 initially selects the first clock signal for the output clock signal 504. The multiplexer 420 then switches the output clock signal from the first clock signal to the second clock signal, as indicated in FIG. 5. In this example, the switch from the first clock signal to the second clock signal causes the multiplexer 420 to swallow the clock edge 515. The swallowing of the clock edge 515 causes the deserializer 170 to delay the capture of a bit from the serial data stream by one unit interval (i.e., one bit period), which shifts the word boundary of the deserializer 170 by one bit position. As shown in FIG. 5, the clock switching changes the falling clock edge 530 to a rising clock edge 535. However, this change does not affect the data capture operations of the deserializer 170 since the deserializer 170 captures data on both rising clock edges and falling clock edges.

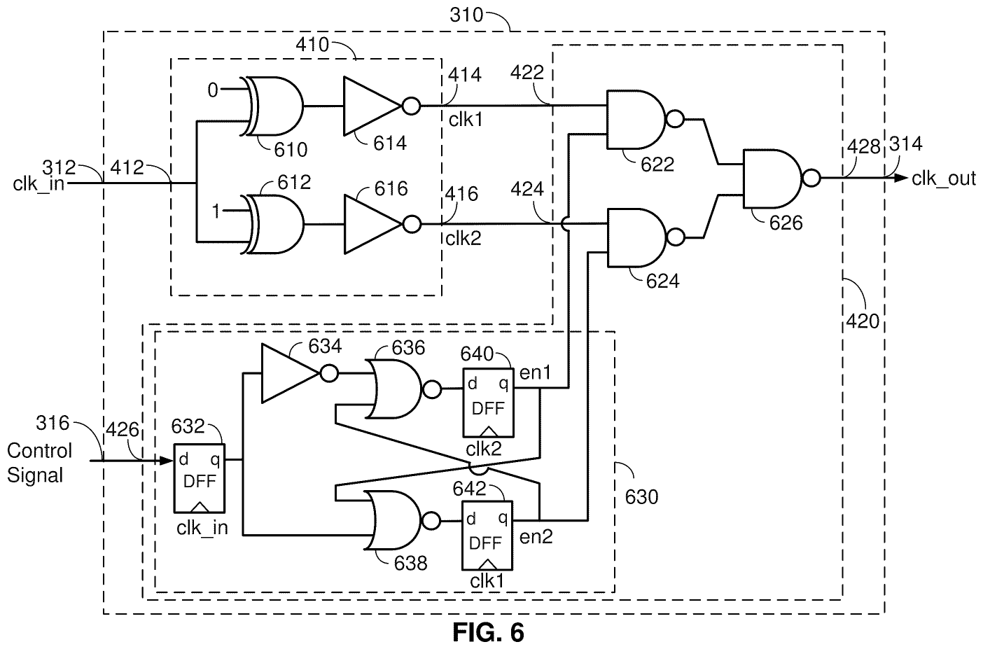

FIG. 6 shows an exemplary implementation of the complementary clock generator 410 and the multiplexer 420 according to certain aspects. In this example, the complementary clock generator 410 includes a first exclusive-OR (XOR) gate 610, a second XOR gate 612, a first inverter 614, and a second inverter 616. The first XOR gate 610 has a first input coupled to logic zero (e.g., ground potential) and a second input coupled to the input 412. The first inverter 614 is coupled to the between the output of the first XOR gate 610 and the first output 414. The second XOR gate 612 has a first input coupled to logic one (e.g., a supply voltage) and a second input coupled to the input 412. The second inverter 616 is coupled to the between the output of the second XOR gate 612 and the second output 416.

In this example, coupling the first input of the first XOR gate 610 to logic zero causes the first XOR gate 610 to pass the input clock signal (labeled “clk_in”), and coupling the first input of the second XOR gate 612 to logic one causes the second XOR gate 612 to invert the input clock signal (labeled “clk_in”). As a result, the first XOR gate 610 and the second XOR gate 612 output complementary clock signals to the inverters 614 and 616. This causes the inverters 614 and 616 to output complementary clock signals (i.e., the first clock signal and the second clock signal) at the outputs 414 and 416.

It is to be appreciated that the complementary clock generator 410 is not limited to the exemplary implementation shown in FIG. 6, and that the complementary clock generator 410 may be implemented with other circuits configured to generate complementary clocks based on the input clock signal (labeled “clk_in”).

In the example shown in FIG. 6, the multiplexer 420 is implemented with a glitch-free multiplexer including circuits for preventing glitches at the output 428 of the multiplexer 420, as discussed further below. For example, a glitch may be in the form of a narrow pulse that can cause timing issues in the deserializer 170 if allowed to propagate to the deserializer 170.

In this example, the multiplexer 420 includes a first NAND gate 622, a second NAND gate 624, and a third NAND gate 626. The first NAND gate 622 has a first input coupled to the first input 422 of the multiplexer 420, and a second input configured to receive a first enable signal (labeled “en1”). The second NAND gate 624 has a first input coupled to the second input 424 of the multiplexer 420, and a second input configured to receive a second enable signal (labeled “en2”). The third NAND gate 626 has a first input coupled to the output of the first NAND gate 622, and a second input coupled to the output of the second NAND gate 624. The output of the third NAND gate 626 is coupled to the output 428 of the multiplexer 420.

In this example, the NAND gates 622, 624, and 626 form a NAND-based multiplexer configured to select the first clock signal or the second clock signal based on the logic states of the first enable signal and the second enable signal. More particularly, the NAND-based multiplexer selects the first clock signal when the first enable signal is logic one (i.e., high) and the second enable signal is logic zero (i.e., low), and selects the second clock signal when the first enable signal is logic zero (i.e., low) and the second enable signal is logic one (i.e., high).

In this example, the multiplexer 420 also includes a circuit 630 configured to generate the first enable signal (labeled “en1”) and the second enable signal (labeled “en2”) based on the control signal at the select input 426. The circuit 630 includes a first flip-flop 632, an inverter 634, a first NOR gate 636, a second NOR gate 638, a second flip-flop 640, and a third flip-flop 642.

In the example in FIG. 6, the first flip-flop 632 is clocked by the input clock signal (labeled “clk_in), the second flip-flop 640 is clocked by the second clock signal (labeled “clk2”), and the third flip-flop 642 is clocked by the first clock signal (labeled “clk1”). In this example, each of the flip-flops 632, 640, and 642 may be positive edge triggered, in which each of the flip-flops 632, 640, and 642 is configured to latch the logic state at an input (labeled “d”) of the flip-flop on a rising edge of the respective clock signal and output the latched logic state at an output (labeled “q”) of the flip-flop. However, it is to be appreciated that the present disclosure is not limited to this example.

In this example, the input of the first flip-flop 632 is coupled to the select input 426. The inverter 634 is coupled to between the output of the first flip-flop 632 and a first input of the first NOR gate 636, and a first input of the second NOR gate 638 is coupled to the output of the flip-flop 632. The input of the second flip-flop 640 is coupled to the output of the first NOR gate 636, and the output of the second flip-flop 640 is coupled to a second input of the second NOR gate 638 and the second input of the first NAND gate 622. The input of the third flip-flop 642 is coupled to the output of the second NOR gate 638, and the output of the third flip-flop 642 is coupled to a second input of the first NOR gate 636 and the second input of the second NAND gate 624. The output of the second flip-flop 640 outputs the first enable signal (labeled “en1”) and the output of the third flip-flop 642 outputs the second enable signal (labeled “en2”), as shown in FIG. 6.

In this example, the circuit 630 asserts the first enable signal high and asserts the second enable signal low when the control signal at the select input 426 is high (i.e., logic one). Thus, in this example, the first clock signal is selected when the control signal is logic one. The circuit 630 asserts the first enable signal low and asserts the second enable signal low when the control signal at the select input 426 is low (i.e., logic zero). Thus, in this example, the second clock signal is selected when the control signal is logic zero.

In this example, the multiplexer 420 switches from the second clock signal to the first clock signal in response to a rising edge of the control signal (i.e., transition from low to high). To prevent a glitch during the clock switch, the circuit 630 deselects the second clock signal (i.e., transitions the second enable signal from high to low) when the second clock signal is low. The circuit 630 then selects the first clock signal (i.e., transitions the first enable signal from low to high) when the first clock signal is low.

The multiplexer 420 switches from the first clock signal to the second clock signal in response to a falling edge of the control signal (i.e., transition from high to low). To prevent a glitch during the clock switch, the circuit 630 deselects the first clock signal (i.e., transitions the first enable signal from high to low) when the first clock signal is low. The circuit 630 then selects the second clock signal (i.e., transitions the second enable signal from low to high) when the second clock signal is low.

It is to be appreciated that the present disclosure is not limited to the above examples. For example, in other implementations, the multiplexer 420 may be configured to switch from the second clock signal to the first clock signal in response to a falling edge of the control signal and switch from the first clock signal to the second clock signal in response to a rising edge of the control signal.

It is also to be appreciated that the multiplexer 420 is not limited to NAND gates for multiplexing, and that the multiplexing may be implemented with other types of logic gates and/or other combinations of logic gates. It is also to be appreciated that the circuit 630 is not limited to the exemplary implementation shown in FIG. 6, and that the circuit 630 may be implemented with other combinations of flip-flops and/or logic gates to implement glitch-free clock switching. It is also to be appreciated that the multiplexer 420 may include one or more additional elements in the clock paths in some implementations. It is also to be appreciated that a logic gate (e.g., NAND gate) may be implemented with a combination of logic gates.

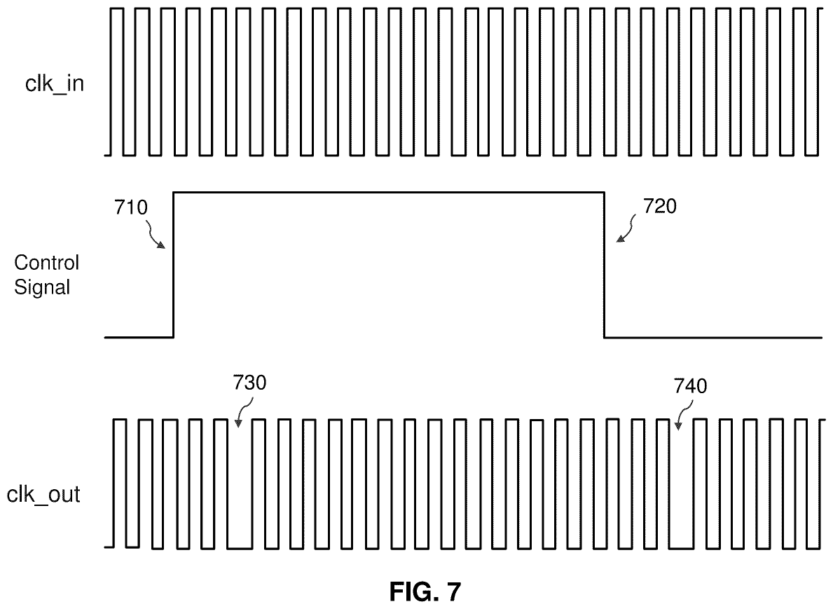

FIG. 7 is a timing diagram showing an example of the input clock signal (labeled “clk_in”) and the output clock signal (labeled “clk_out”) of the edge swallower 310 according to certain aspects. In this example, the control signal has a rising edge 710 (i.e., toggles low to high) and a falling edge 720 (i.e., toggles high to low). In response to the rising edge 710, the multiplexer 420 switches from the second clock signal to the first clock signal, which results in a first edge swallow 730 of the output clock signal. The first edge swallow 730 causes the deserializer 170 to shift the word boundary by one bit position. In response to the falling edge 720, the multiplexer 420 switches from the first clock signal to the second clock signal, which results in a second edge swallow 740 of the output clock signal. The second edge swallow 740 causes the deserializer 170 to shift the word boundary by another bit position. Thus, in this example, the controller 320 causes the edge swallower 310 to swallow a clock edge by toggling the control signal high to low (i.e., one to zero) or low to high (i.e., zero to one).

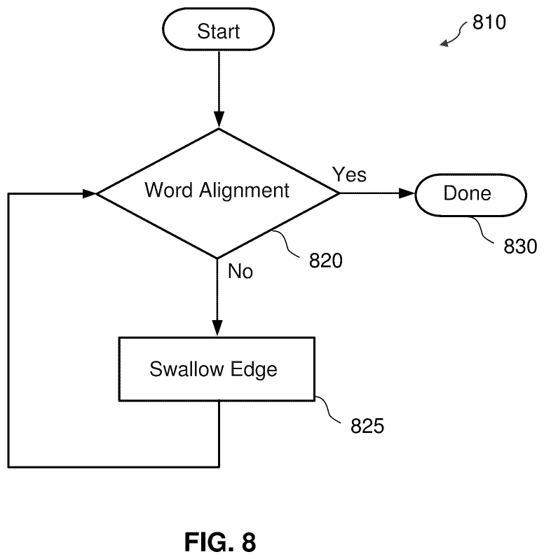

FIG. 8 shows an exemplary word alignment method 810 that may be performed by the controller 320 and the edge swallower 310 according to certain aspects. In this example, the first chip 110 transmits a known pattern (e.g., pattern of bits) to the second chip 112 via the first link 114 one or more times.

At block 820, the controller 320 determines whether there is word alignment between the first chip 110 and the second chip 112. For example, the controller 320 may compare a data word output by the deserializer 170 with the known pattern and determine whether there is word alignment based on the comparison. For example, the controller 320 may determine word misalignment when the data word does not match the pattern, and determine word alignment when the data word matches the pattern. If there is word alignment, then the controller 320 may be done with the word alignment method 810 at block 830. If there is word misalignment, then the controller 320 proceeds to block 825.

At block 825, the controller 320 causes the edge swallower 310 to swallow an edge of the clock signal of the deserializer 170. The edge swallowing causes the word boundary at the deserializer 170 to shift by one bit position. For example, the controller 320 may cause the edge swallower 310 to swallow the edge by toggling the control signal high to low (i.e., one to zero) or low to high (i.e., zero to one). After the edge swallowing, the controller 320 returns to block 820 to determine whether word alignment has been achieved after the word boundary shift. The controller 320 and the edge swallower 310 may repeat blocks 820 and 825 until word alignment is achieved. Thus, the controller 320 may cause the edge swallower 310 to sequentially swallow edges of the clock signal to sequentially shift the word boundary until word alignment is achieved.

In the above example, the system 100 uses half-rate clock signals to time the operations of the serializer 120 and the deserializer 170, in which frequency of the half-rate clock signals is equal to half the frequency or data rate of the serial data stream. However, it is to be appreciated that the present disclosure is not limited to this example. In other implementations, the system 100 may use full-rate clock signals to time the operations of the serializer 120 and the deserializer 170, in which the frequency of the full-rate clock signals is equal to the frequency or data rate of the serial data stream, as discussed further below.

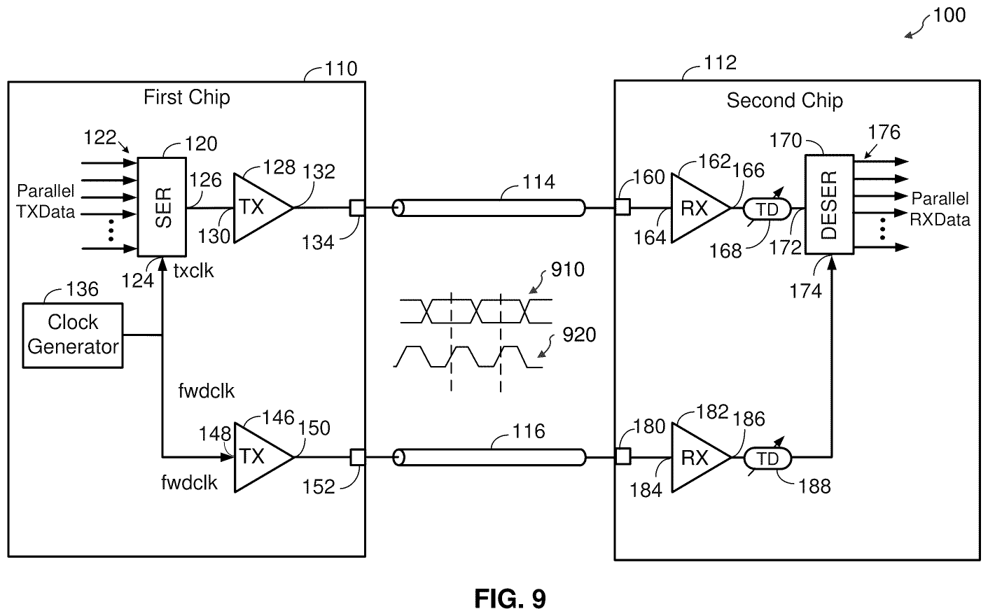

In this regard, FIG. 9 shows an example in which the system 100 uses full-rate clock signals for SerDes communication according to certain aspects. In this example, the clock generator 136 is configured to generate a transmit clock signal (labeled “txclk”) and output the transmit clock signal to the clock input 124 of the serializer 120 and the input 148 of the second driver 146. In this example, the transmit clock signal is also used for the forward clock signal, which the second driver 146 transmits to the second chip 112 via the second link 116.

As discussed above, the serializer 120 receives parallel data at the parallel inputs 122, converts the parallel data into a serial data stream, and outputs the serial data stream at the output 126. In this example, the serializer 120 is configured to output one bit of the serial data stream for each rising edge of the transmit clock signal. Since the transmit clock signal has one rising edge per clock period, this causes the serializer 120 to output one bit of the serial data stream per clock period. As a result, the data rate of the serial data stream is equal to the frequency of the transmit clock signal. The first driver 128 transmits the serial data stream to the second chip 112 via the first link 114.

At the second chip 112, the first receiver 162 receives the serial data stream at the input 164 via the first link 114 and outputs the received serial data stream, which is routed to the data input 172 of the deserializer 170 (e.g., through the first tunable delay circuit 168). The second receiver 182 receives the forward clock signal at the input 184 via the second link 116 and outputs the received forward clock signal, which is routed to the clock input 174 of the deserializer 170 (e.g., through the second tunable delay circuit 188).

In this example, the deserializer 170 is configured to sequentially capture data bits in the received serial data stream on rising edges of the received forward clock signal, and output the captured data bits in parallel at the parallel outputs 176. To reliably capture data bits in the received serial data stream at the deserializer 170, the rising edges of the forward clock signal at the clock input 174 may be centered between data transitions in the received serial data stream. In this regard, FIG. 9 shows an example of the received serial data stream 910 and an example of the forward clock signal 920 at the clock input 174 in which the rising edges of the forward clock signal 920 are centered between the data transitions in the received serial data stream 910. In this example, the clock path from the clock generator 136 to the deserializer 170 may include an inverter (which provides a phase shift of 180 degrees) to help center the rising edges of the forward clock signal 920 between the data transitions. However, it is to me appreciated that the present disclosure is not limited to this example.

In this example, full-rate clock signals (i.e., the transmit clock signal and the forward clock signal) are used to time the operations of the serializer 120 and the deserializer 170, in which the frequency of the full-rate clock signals is equal to the frequency or data rate of the serial data stream. In this example, the word boundary at the deserializer 170 may be shifted to achieve word alignment by providing a pulse swallower in the clock path of the deserializer 170.

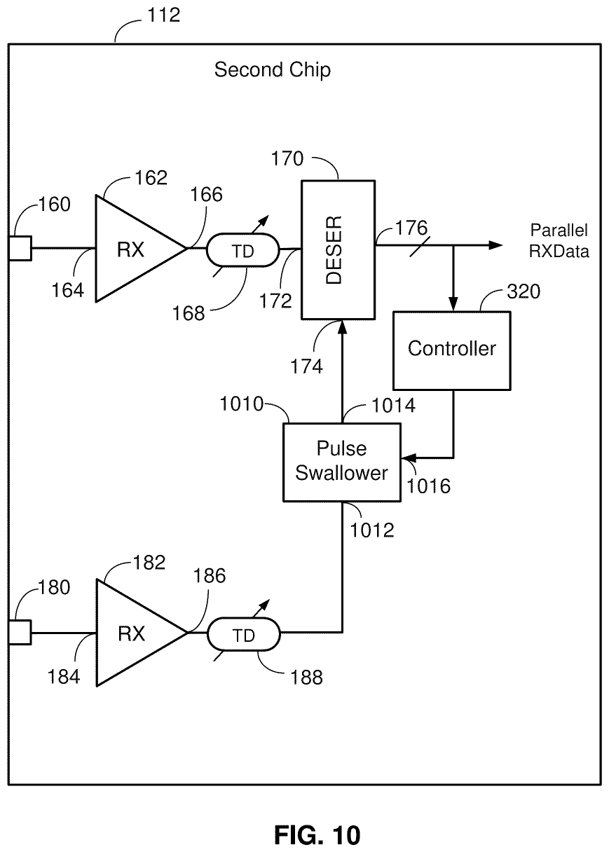

In this regard, FIG. 10 shows an example in which the second chip 112 includes a pulse swallower 1010 in the clock path of the deserializer 170. In the example shown in FIG. 10, the pulse swallower 1010 is positioned between the second tunable delay circuit 188 and the clock input 174 of the deserializer 170. However, it is to be appreciated that the present disclosure is not limited to this example, and that the pulse swallower 1010 may be positioned at other locations in the clock path of the deserializer 170 in other implementations.

In this example, the pulse swallower 1010 has a clock input 1012, a control input 1016, and an output 1014. The clock input 1012 of the pulse swallower 1010 is coupled to the second receiver 182 through the second tunable delay circuit 188 (which may be omitted in some implementations). In this example, the clock input 1012 receives the clock signal received by the second receiver 182 from the first chip 110 (shown in FIG. 9). However, it is to be appreciated that the present disclosure is not limited to this example, and that the clock signal may come from another source (e.g., a clock data recovery circuit located on the second chip 112) in other implementations. The output 1014 of the pulse swallower 1010 is coupled to the clock input 174 of the deserializer 170, and the control input 1016 of the pulse swallower 1010 is coupled to the controller 320.

The pulse swallower 1010 is configured to shift the word boundary at the deserializer 170 by swallowing pulses of the clock signal received at the input 1012 and outputting the clock signal after the pulse swallowing to the clock input 174 of the deserializer 170. For example, the pulse swallower 1010 may shift the word boundary at the deserializer 170 by one bit position for each pulse of the clock signal that is swallowed. In certain aspects, the pulse swallower 1010 is configured to swallow pulses of the clock signal based on a control signal received at the control input 1016 from the controller 320, as discussed further below.

In certain aspects, the controller 320 is configured to cause the pulse swallower 1010 to sequentially shift the word boundary at the deserializer 170 until word alignment is achieved between the serializer 120 and the deserializer 170. For example, during an initial setup, the first chip 110 may transmit a known pattern (e.g., pattern of bits) to the second chip 112 one or more times via the first link 114. In this example, word alignment occurs when a data word output by the deserializer 170 matches the pattern. In this example, the controller 1020 may cause the pulse swallower 1010 to sequentially shift the word boundary at the deserializer 170 (e.g., sequentially swallow clock pulses) until a data word output by the deserializer 170 matches the pattern indicating word alignment. As a result, word alignment is achieved without the need for data encoding or an extra lane to indicate word boundaries, both of which increase power and reduce link efficiency. In addition, word alignment is achieved without adding latency to the data path.

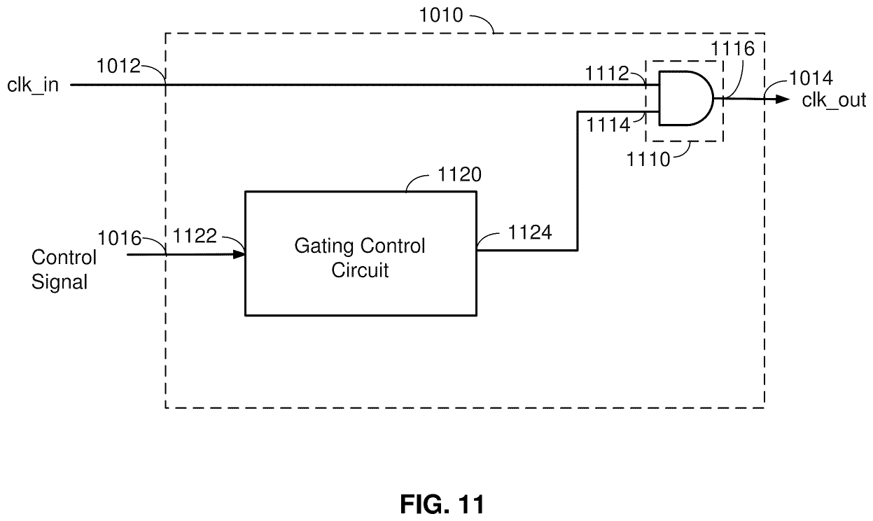

FIG. 11 shows an exemplary implementation of the pulse swallower 1010 according to certain aspects. In this example, the pulse swallower 1010 includes a clock gating circuit 1110 and a gating control circuit 1120. The clock gating circuit 1110 has a clock input 1112 coupled to the input 1012 of the pulse swallower 1010, a control input 1114, and an output 1116 coupled to the output 1014 of the pulse swallower 1010. The gating control circuit 1120 has an input 1122 coupled to the control input 1016, and an output 1124 coupled to the control input 1114 of the clock gating circuit 1110.

In operation, the clock gating circuit 1110 is configured to selectively gate (i.e., block) the input clock signal based on the logic state of a gate control signal at the control input 1114. For example, the clock gating circuit 1110 may be configured to pass the input clock signal when the gate control signal is high, and gate the input clock signal when the gate control signal is low, or vice versa. In the example shown in FIG. 11, the clock gating circuit 1110 includes an AND gate having a first input coupled to the clock input 1112, a second input coupled to the control input 1114, and an output coupled to the output 1116. In this example, the clock gating circuit 1110 passes the input clock signal when gate control signal is high and gates the input clock signal when the gate control signal is low. However, it is to be appreciated that the clock gating circuit 1110 is not limited to an AND gate, and that the clock gating circuit 1110 may be implemented with other types of logic gates.

The gating control circuit 1120 is configured to receive the control signal from the controller 320 at the input 1122 and generate the gate control signal for the clock gating circuit 1110 based on the control signal from the controller 320. For example, the gating control circuit 1120 may be configured to cause the clock gating circuit 1110 to swallow a pulse of the input clock signal based on the control signal from the controller 320. In this example, the gating control circuit 1120 may cause the clock gating circuit 1110 to swallow a clock pulse by causing the clock gating circuit 1110 to gate the input clock signal for one clock period. For the example where the clock gating circuit 1110 gates the input clock signal when the gate control signal is low, the gating control circuit 1120 may cause the clock gating circuit to swallow a clock pulse by making the gate control signal low for one clock period

In one example, the gating control circuit 1120 may be configured to cause the clock gating circuit 1110 to swallow a clock pulse in response to a rising edge of the control signal from the controller 320. In this example, the controller 320 causes the pulse swallower 1010 to swallow a clock pulse by toggling the control signal low to high (i.e., rising edge). In another example, the gating control circuit 1120 may be configured to cause the clock gating circuit 1110 to swallow a clock pulse in response to a falling edge of the control signal from the controller 320. In this example, the controller 320 causes the pulse swallower 1010 to swallow a clock pulse by toggling the control signal high to low (i.e., falling edge). In another example, the gating control circuit 1120 may be configured to cause the clock gating circuit 1110 to swallow a clock pulse in response to either a rising edge or a falling edge of the control signal from the controller 320. In this example, the controller 320 causes the pulse swallower 1010 to swallow a clock pulse by toggling the control signal high to low or low to high.

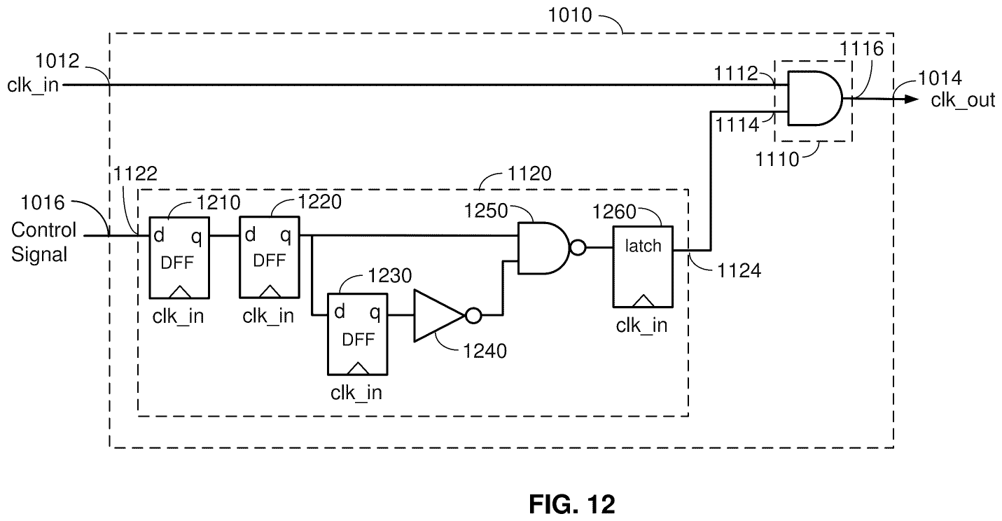

FIG. 12 shows an exemplary implementation of the gating control circuit 1120 according to certain aspects. In this example, the gating control circuit 1120 includes a first flip-flop 1210, a second flip-flop 1220, a third flip-flop 1230, an inverter 1240, a NAND gate 1250, and a latch 1260.

In the example in FIG. 12, each of the flip-flops 1210, 1220, and 1230 is clocked by the input clock signal (labeled “clk_in). In this example, each of the flip-flops 1210, 1220, and 1230 may be positive edge triggered, in which each of the flip-flops 1210, 1220, and 1230 is configured to latch the logic state at an input (labeled “d”) of the flip-flop on a rising edge of the input clock signal and output the latched logic state at an output (labeled “q”) of the flip-flop. However, it is to be appreciated that the present disclosure is not limited to this example. The latch 1260 is clocked by the input clock signal and may be configured to pass the logic value at the input of the latch 1260 to the output of the latch 1260 when the input clock signal is low, and hold the logic value at the output of the latch 1260 when the input clock signal is high.

In this example, the input of the first flip-flop 1210 is coupled to the input 1122, and the input of the second flip-flop 1220 is coupled to the output of the first flip-flop 1210. The NAND gate 1250 has a first input coupled to the output of the second flip-flop 1220, and a second input. The input of the third flip-flop 1230 is coupled to the output of the second flip-flop 1220, and the inverter 1240 is coupled between the output of the third flip-flop 1230 and the second input of the NAND gate 1250. The input of the latch 1260 is coupled to the output of the NAND gate 1250, and the output of the latch 1260 is coupled to the output 1124 of the gating control circuit 1120.

In this example, the third flip-flop 1230 and the inverter 1240 cause the gating control circuit 1120 to gate the input clock signal for one period of the input clock signal when the control signal from the controller 320 triggers a pulse swallow. The latch 1260 helps prevent a glitch at the output 1116 of the clock gating circuit 1110. This is because the latch 1260 prevents the gate control signal from toggling when the input clock signal is high by holding the gate control signal when the input clock signal is high.

It is to be appreciated that the gating control circuit 1120 is not limited to the exemplary implementation shown in FIG. 12. For example, it is to be appreciated that one or both of the flip-flops 1210 and 1220 may be omitted in some implementations. It is also to be appreciated that the gating control circuit 1120 is not limited to the NAND gate 1250, and that other type of logic gates may be used in other implementations (e.g., OR gate, NOR gate, XNOR gate, XOR gate, or any combination thereof).

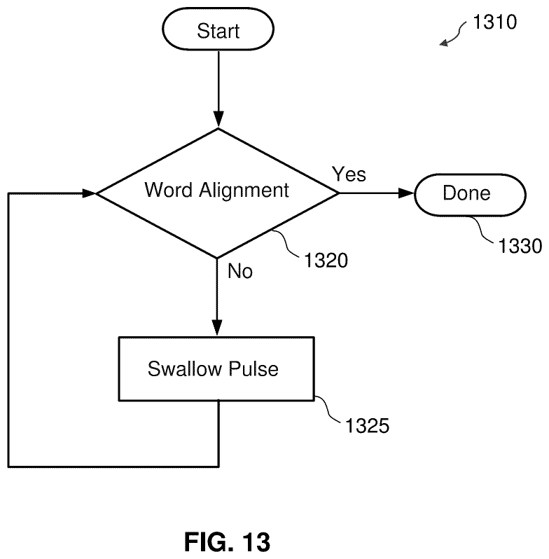

FIG. 13 shows an exemplary word alignment method 1310 that may be performed by the controller 320 and the pulse swallower 1010 according to certain aspects. In this example, the first chip 110 transmits a known pattern (e.g., pattern of bits) to the second chip 112 via the first link 114 one or more times.

At block 1320, the controller 320 determines whether there is word alignment between the first chip 110 and the second chip 112. For example, the controller 320 may compare a data word output by the deserializer 170 with the known pattern and determine whether there is word alignment based on the comparison. For example, the controller 320 may determine word misalignment when the data word does not match the pattern, and determine word alignment when the data word matches the pattern. If there is word alignment, then the controller 320 may be done with the word alignment method 1310 at block 1330. If there is word misalignment, then the controller 320 proceeds to block 1325.

At block 1325, the controller 320 causes the pulse swallower 1010 to swallow a pulse of the clock signal of the deserializer 170. The pulse swallowing causes the word boundary at the deserializer 170 to shift by one bit position. For example, depending on the implementation of the pulse swallower 1010, the controller 320 may cause the pulse swallower 1010 to swallow the pulse by toggling the control signal high to low, toggling the control signal low to high, or cither togging the control signal high to low or low to high. After the pulse swallowing, the controller 320 returns to block 1320 to determine whether word alignment has been achieved after the word boundary shift. The controller 320 and the pulse swallower 1010 may repeat blocks 1320 and 1325 until word alignment is achieved. Thus, the controller 320 may cause the pulse swallower 1010 to sequentially swallow pulses of the clock signal to sequentially shift the word boundary until word alignment is achieved.

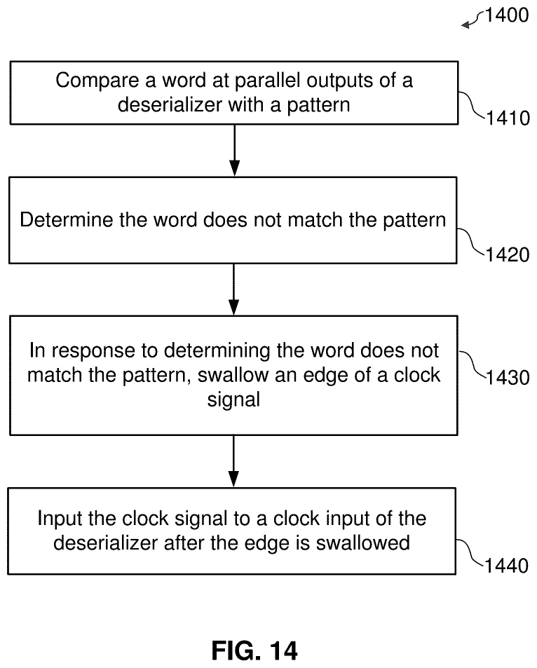

FIG. 14 shows an exemplary word alignment method 1400 according to certain aspects.

At block 1410, a word at parallel outputs of a deserializer is compared with a pattern. For example, the deserializer may correspond to the deserializer 170 and the parallel output may correspond to the parallel outputs 176. The comparison may be performed by the controller 320.

At block 1420, the word is determined not to match the pattern. For example, the controller 320 may determine the word does not match the pattern, which indicates word misalignment.

At block 1430, in response to determining the word does not match the pattern, an edge of a clock signal is swallowed. For example, the edge swallowing may be performed by the edge swallower 310.

At block 1440, the clock signal is input to a clock input of the deserializer after the edge is swallowed. For example, the clock input may correspond to the clock input 174.

In certain aspects, swallowing the edge of the clock signal includes switching a source of the clock signal from a first clock signal to a second clock signal, wherein the first clock signal and the second clock signal are complementary. For example, the first clock signal may correspond to the first clock signal clk1, the second clock signal clk may correspond to the to the second clock signal clk2, and the clock signal may correspond to the clock signal clk_out. In this example, the multiplexer 420 may switch the source of the clock signal clk_out from the first clock signal clk1 to the second clock signal clk2.

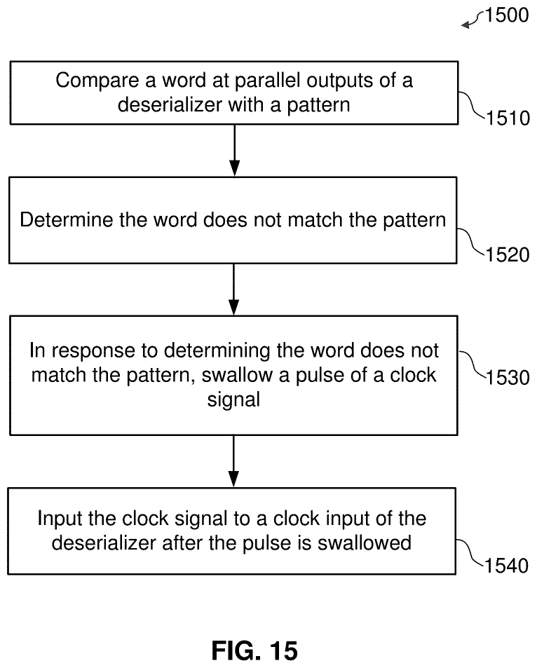

FIG. 15 shows an exemplary word alignment method 1500 according to certain aspects.

At block 1510, a word at parallel outputs of a deserializer is compared with a pattern. For example, the deserializer may correspond to the deserializer 170 and the parallel output may correspond to the parallel outputs 176. The comparison may be performed by the controller 320.

At block 1520, the word is determined not to match the pattern. For example, the controller 320 may determine the word does not match the pattern, which indicates word misalignment.

At block 1530, in response to determining the word does not match the pattern, a pulse of a clock signal is swallowed. For example, the pulse swallowing may be performed by the pulse swallower 1010.

At block 1540, the clock signal is input to a clock input of the deserializer after the pulse is swallowed. For example, the clock input may correspond to the clock input 174.

In certain aspects, swallowing the pulse of the clock signal includes gating the clock signal for a period of the clock signal. For example, the clock signal may be gated by the clock gating circuit 1110.

Implementation examples are described in the following numbered clauses:

1. A system, comprising:
a deserializer having a data input, a clock input, and parallel outputs, wherein the deserializer is configured to receive a serial data stream at the data input, convert the serial data stream into parallel data, and output the parallel data at the parallel outputs; and
an edge swallower coupled to the clock input of the deserializer.

2. The system of clause 1, wherein the deserializer is configured to sequentially capture bits in the serial data stream on rising edges and falling edges at the clock input of the deserializer, wherein the parallel data include the captured bits.

3. The system of clause 1 or 2, further comprising a controller coupled to the parallel outputs of the deserializer and the edge swallower, wherein the controller is configured to:
compare a word in the parallel data with a pattern; and
cause the edge swallower to swallow an edge of a clock signal if the word does not match the pattern, wherein the edge swallower outputs the clock signal to the clock input of the deserializer after the edge is swallowed.

4. The system of any one of clauses 1 to 3, wherein the edge swallower comprises:
a complementary clock generator configured to receive an input clock signal, and generate a first clock signal and a second clock signal based on the input clock signal, wherein the first clock signal and the second clock signal are complementary; and
a multiplexer having a first input, a second input, and an output, wherein the first input is configured to receive the first clock signal, the second input is configured to receive the second clock signal, and the output of the multiplexer is coupled to the clock input of the deserializer.

5. The system of clause 4, further comprising a controller coupled to the parallel outputs of the deserializer and the multiplexer, wherein the controller is configured to: compare a word in the parallel data with a pattern; and
cause the multiplexer to switch between the first clock signal and the second clock signal if the word does not match the pattern.

6. The system of clause 4 or 5, wherein the multiplexer is configured to receive a control signal, and switch between the first clock signal and the second clock signal in response to a rising edge or a falling edge in the control signal.

7. The system of any one of clauses 1 to 6, wherein the deserializer is integrated on a first chip, and the system further comprises:
a first receiver configured to receive the serial data stream from a second chip via a first link, and output the serial data stream to the data input of the deserializer; and
a second receiver configured to receive a clock signal from the second chip via a second link, and output the clock signal at an output of the second receiver, wherein the edge swallower is coupled between the output of the second receiver and the clock input of the deserializer.

8. The system of clause 7, wherein the edge swallower is configured to receive a control signal, and swallow an edge in the clock signal in response to an edge in the control signal.

9. A system, comprising:
a deserializer having a data input, a clock input, and parallel outputs, wherein the deserializer is configured to receive a serial data stream at the data input, convert the serial data stream into parallel data, and output the parallel data at the parallel outputs; and
a pulse swallower coupled to the clock input of the deserializer.

10. The system of clause 9, wherein the deserializer is configured to sequentially capture bits in the serial data stream on rising edges at the clock input of the deserializer, wherein the parallel data include the captured bits.

11. The system of clause 9 or 10, further comprising a controller coupled to the parallel outputs of the deserializer and the pulse swallower, wherein the controller is configured to:
compare a word in the parallel data with a pattern; and
cause the pulse swallower to swallow a pulse of a clock signal if the word does not match the pattern, wherein the pulse swallower outputs the clock signal to the clock input of the deserializer after the pulse is swallowed.

12. The system of any one of clauses 9 to 11, wherein the pulse swallower comprises:
a clock gating circuit having an input and an output, wherein the input of the clock gating circuit is configured to receive a clock signal, and the output of the clock gating circuit is coupled to the clock input of the deserializer; and
a gating control circuit configured to receive a control signal, and cause the clock gating circuit to gate a pulse in the clock signal in response to an edge in the control signal, wherein the clock gating circuit outputs the clock signal to the clock input of the deserializer after the pulse is gated.

13. The system of clause 12, wherein the edge is a rising edge.

14. The system of clause 12, wherein the edge is a falling edge.

15. The system of any one of clauses 12 to 14, further comprising a controller coupled to the parallel outputs of the deserializer and the gating control circuit, wherein the controller is configured to:
output the control signal to the gating control circuit;
compare a word in the parallel data with a pattern; and
toggle the control signal to generate the edge if the word does not match the pattern.

16. The system of any one of clauses 9 to 15, wherein the deserializer is integrated on a first chip, and the system further comprises:
a first receiver configured to receive the serial data stream from a second chip via a first link, and output the serial data stream to the data input of the deserializer; and
a second receiver configured to receive a clock signal from the second chip via a second link, and output the clock signal at an output of the second receiver, wherein the pulse swallower is coupled between the output of the second receiver and the clock input of the deserializer.

17. The system of clause 16, wherein the pulse swallower is configured to receive a control signal, and swallow a pulse in the clock signal in response to an edge in the control signal.

18. A method of word alignment, comprising:
comparing a word at parallel outputs of a deserializer with a pattern;
determining the word does not match the pattern;
in response to determining the word does not match the pattern, swallowing an edge of a clock signal; and
inputting the clock signal to a clock input of the deserializer after the edge is swallowed.

19. The method of clause 18, wherein swallowing the edge of the clock signal comprises switching the source of the clock signal from a first clock signal to a second clock signal, wherein the first clock signal and the second clock signal are complementary.

20. A method of word alignment, comprising:
comparing a word at parallel outputs of a deserializer with a pattern;
determining the word does not match the pattern;
in response to determining the word does not match the pattern, swallowing a pulse of a clock signal; and
inputting the clock signal to a clock input of the deserializer after the pulse is swallowed.

21. The method of clause 20, wherein swallowing the pulse of the clock signal comprises gating the clock signal for a period of the clock signal.

Within the present disclosure, the word “exemplary” is used to mean “serving as an example, instance, or illustration.” Any implementation or aspect described herein as “exemplary” is not necessarily to be construed as preferred or advantageous over other aspects of the disclosure. Likewise, the term “aspects” does not require that all aspects of the disclosure include the discussed feature, advantage or mode of operation. The term “coupled” is used herein to refer to the direct or indirect electrical coupling between two structures. It is also to be appreciated that the term “ground” may refer to a DC ground or an AC ground, and thus the term “ground” covers both possibilities. It is also to be appreciated than an “input” may be a single-ended input, a differential input, or one of two inputs of a differential input, and an “output” may be a single-ended output, a differential output, or one of two outputs of a differential output. The term “approximately” means within a range of between 90 percent and 110 percent of the stated value.

Any reference to an element herein using a designation such as “first,” “second,” and so forth does not generally limit the quantity or order of those elements. Rather, these designations are used herein as a convenient way of distinguishing between two or more elements or instances of an element. Thus, a reference to first and second elements does not mean that only two elements can be employed, or that the first element must precede the second element. For example, the first chip 110 and the second chip 112 may also be referred to as the second chip and the first chip, respectively, to distinguish between the two chips.

The previous description of the disclosure is provided to enable any person skilled in the art to make or use the disclosure. Various modifications to the disclosure will be readily apparent to those skilled in the art, and the generic principles defined herein may be applied to other variations without departing from the spirit or scope of the disclosure. Thus, the disclosure is not intended to be limited to the examples described herein but is to be accorded the widest scope consistent with the principles and novel features disclosed herein.

What is claimed is:

1. A system, comprising:
a deserializer having a data input, a clock input, and parallel outputs, wherein the deserializer is configured to receive a serial data stream at the data input, convert the serial data stream into parallel data, and output the parallel data at the parallel outputs; and
an edge swallower coupled to the clock input of the deserializer.

2. The system of claim 1, wherein the deserializer is configured to sequentially capture bits in the serial data stream on rising edges and falling edges at the clock input of the deserializer, wherein the parallel data include the captured bits.

3. The system of claim 1, further comprising a controller coupled to the parallel outputs of the deserializer and the edge swallower, wherein the controller is configured to:
compare a word in the parallel data with a pattern; and
cause the edge swallower to swallow an edge of a clock signal if the word does not match the pattern, wherein the edge swallower outputs the clock signal to the clock input of the deserializer after the edge is swallowed.

4. The system of claim 1, wherein the edge swallower comprises:
a complementary clock generator configured to receive an input clock signal, and generate a first clock signal and a second clock signal based on the input clock signal, wherein the first clock signal and the second clock signal are complementary; and
a multiplexer having a first input, a second input, and an output, wherein the first input is configured to receive the first clock signal, the second input is configured to receive the second clock signal, and the output of the multiplexer is coupled to the clock input of the deserializer.

5. The system of claim 4, further comprising a controller coupled to the parallel outputs of the deserializer and the multiplexer, wherein the controller is configured to:
compare a word in the parallel data with a pattern; and
cause the multiplexer to switch between the first clock signal and the second clock signal if the word does not match the pattern.

6. The system of claim 4, wherein the multiplexer is configured to receive a control signal, and switch between the first clock signal and the second clock signal in response to a rising edge or a falling edge in the control signal.

7. The system of claim 1, wherein the deserializer is integrated on a first chip, and the system further comprises:
a first receiver configured to receive the serial data stream from a second chip via a first link, and output the serial data stream to the data input of the deserializer; and
a second receiver configured to receive a clock signal from the second chip via a second link, and output the clock signal at an output of the second receiver, wherein the edge swallower is coupled between the output of the second receiver and the clock input of the deserializer.

8. The system of claim 7, wherein the edge swallower is configured to receive a control signal, and swallow an edge in the clock signal in response to an edge in the control signal.

9. A system, comprising:
a deserializer having a data input, a clock input, and parallel outputs, wherein the deserializer is configured to receive a serial data stream at the data input, convert the serial data stream into parallel data, and output the parallel data at the parallel outputs; and
a pulse swallower coupled to the clock input of the deserializer.

10. The system of claim 9, wherein the deserializer is configured to sequentially capture bits in the serial data stream on rising edges at the clock input of the deserializer, wherein the parallel data include the captured bits.

11. The system of claim 9, further comprising a controller coupled to the parallel outputs of the deserializer and the pulse swallower, wherein the controller is configured to:
compare a word in the parallel data with a pattern; and
cause the pulse swallower to swallow a pulse of a clock signal if the word does not match the pattern, wherein the pulse swallower outputs the clock signal to the clock input of the deserializer after the pulse is swallowed.

12. The system of claim 9, wherein the pulse swallower comprises:
a clock gating circuit having an input and an output, wherein the input of the clock gating circuit is configured to receive a clock signal, and the output of the clock gating circuit is coupled to the clock input of the deserializer; and
a gating control circuit configured to receive a control signal, and cause the clock gating circuit to gate a pulse in the clock signal in response to an edge in the control signal, wherein the clock gating circuit outputs the clock signal to the clock input of the deserializer after the pulse is gated.

13. The system of claim 12, wherein the edge is a rising edge.

14. The system of claim 12, wherein the edge is a falling edge.

15. The system of claim 12, further comprising a controller coupled to the parallel outputs of the deserializer and the gating control circuit, wherein the controller is configured to:
output the control signal to the gating control circuit;
compare a word in the parallel data with a pattern; and
toggle the control signal to generate the edge if the word does not match the pattern.

16. The system of claim 9, wherein the deserializer is integrated on a first chip, and the system further comprises:
a first receiver configured to receive the serial data stream from a second chip via a first link, and output the serial data stream to the data input of the deserializer; and
a second receiver configured to receive a clock signal from the second chip via a second link, and output the clock signal at an output of the second receiver, wherein the pulse swallower is coupled between the output of the second receiver and the clock input of the deserializer.

17. The system of claim 16, wherein the pulse swallower is configured to receive a control signal, and swallow a pulse in the clock signal in response to an edge in the control signal.

18. A method of word alignment, comprising:
comparing a word at parallel outputs of a deserializer with a pattern;
determining the word does not match the pattern;
in response to determining the word does not match the pattern, swallowing an edge of a clock signal; and
inputting the clock signal to a clock input of the deserializer after the edge is swallowed.

19. The method of claim 18, wherein swallowing the edge of the clock signal comprises switching a source of the clock signal from a first clock signal to a second clock signal, wherein the first clock signal and the second clock signal are complementary.
